(19) United States
(12) Patent Application Publication
(10) Pub. No.: US 2002/0089346 A1
(43) Pub. Date: Jul. 11, 2002

(54) Power supply for individually controlling discharge current and absorbing current as output current supplied to load

(75) Inventor: Yoshihiro Isobe, Tokyo (JP)

Correspondence Address: DARBY & DARBY P.C., 805 Third Avenue, New York, NY, 10022, US

(73) Assignee: Ando Electric Co., Ltd.

(21) Appl. No.: 10/032,699

(22) Filed: Oct. 25, 2001

(30) Foreign Application Priority Data
Dec. 14, 2000 (JP) 2000-380749

(51) Int. Cl. G01R 31/36

(52) U.S. Cl. 324/771

(57) ABSTRACT

A power supply which can individually limit the discharge current and the absorbing current as the output current supplied to the load is disclosed. The power supply comprises an amplification circuit for amplifying and supplying an analog voltage value to the load; a limited current switching circuit, connected to a current limiting control terminal of the amplification circuit, for changing the amount of a limited current which controls the output current of the amplification circuit; and a switching control circuit for outputting a switching signal by which the limited current switching circuit changes the amount of the limited current.

### BACKGROUND OF THE INVENTION

1. Field of the Invention

The present invention relates to a power supply (unit) used in an integrated circuit measurement system or the like.

2. Description of the Related Art

FIG. 2 shows the structure of a conventional power supply. In the figure, reference numeral 1 indicates a CPU (central processing unit), reference numeral 2 indicates a D/A converter, reference numerals 3A, 3B, and 3D indicate resistors, reference numeral 4A indicates an operational amplifier, and reference numeral 7 indicates a load such as an input/output terminal of a semiconductor device.

The CPU 1 is connected to the D/A converter 2, and the D/A converter 2 is connected via the resistor 3A to the negative input terminal of the operational amplifier 4A.

The positive input terminal of the operational amplifier 4A is connected to GND (i.e., earth (or ground) potential), and the output terminal of the operational amplifier 4A is connected to the load 7.

The load 7 is connected to the negative input terminal of the operational amplifier 4A via a feedback resistor 3B, so that a negative feedback loop is formed between the output terminal and the negative input terminal.

The operational amplifier 4A has a current limiting control terminal A, to which an end of the resistor 3D is connected. The other end of the resistor 3D is connected to a terminal of a negative source having a specific negative voltage.

Below, the operation of the conventional power supply will be explained with reference to FIG. 2. This power supply has the following two functions: (i) to apply input voltage VIN, as instructed by the CPU 1, to the load 7 and supply a current from the operational amplifier 4A to the load 7, where the current is required by the load 7 according to the input voltage, and (ii) to limit the output current 10 of the operational amplifier 4A.

First, the operation of supplying current to the load 7 based on the input voltage VIN (see (i) above) will be explained.

A digital signal corresponding to the input voltage VIN is sent to the CPU 1 from an external circuit (not shown). The CPU 1 outputs this input digital signal to the D/A converter 2. The D/A converter 2 converts this digital signal to the input voltage VIN which has an analog value.

When the input voltage VIN is input into the operational amplifier 4A, the operational amplifier 4A amplifies the input voltage up to the output voltage VO, which is applied to the load 7.

The output voltage VO is then assigned to the load 7, and the operational amplifier 4A supplies the output current IO required by the load 7, that is, the current as an output from a stabilized power supply, which is necessary for maintaining the level of the input voltage VIN.

Given voltage value Vin which is the input voltage VIN, resistance R1 of the resistor 3A, and resistance R2 of the feedback resistor 3B, the voltage value Vo of the output voltage VO applied to the load 7 is defined as:

Vo=−(R2/R1)·Vin

where this formula relates to the negative feedback loop. Accordingly, the voltage value Vo of the output voltage VO depends on the voltage value Vin of the input voltage VIN.

Next, the operation of limiting the output current 10 (see (ii) above) will be explained.

The operational amplifier 4A has the current limiting control terminal A, and the limited current IA of the operational amplifier 4A is determined based on (i) the voltage value VB of the negative source B which supplies a negative voltage and (ii) the resistance RD of the resistor 3D.

Given voltage value VA at the current limiting control terminal A, the current value Ia of the limited current IA which flows through the current limiting control terminal A is defined by:

Ia=(VA−VB)/RD

The current value Io of the output current IO of the operational amplifier 4A and the current value Ia of the limited current IA which flows through the current limiting control terminal A have the following relationship:

Io=G·Ia

where G denotes the current amplification factor (i.e., gain) specific to the operational amplifier 4A.

Based on the above limited current IA, the operational amplifier 4A limits the output current IO supplied to the load 7. Here, this limiting of the output current 10 depends only on the resistance RD of the resistor 3D.

In the conventional power supply, the current value Io of the output current 10 which flows from the operational amplifier 4A to the load 7 is determined according to the state of the load 7. In either state of “Io>0” (i.e., discharge current) and “Io<0” (i.e., absorbing current), the limiting of the current value Io of the output current 10 is performed based on the above-explained condition (i.e., on the same condition).

The CPU 1 defines the limited current IA of the operational amplifier 4A by determining the resistance RD, where the resistor 3D is a variable resistor. However, as explained above, the limiting condition of the output current 10 is fixed for both cases of the discharge current and the absorbing current.

Depending on the kind of the load 7, the discharge current and the absorbing current may be different. In this case, the limited current is unnecessarily large with regard to one of the states (i.e., discharge or absorption); thus, it is preferable to set individual limiting values for the discharge current and the absorbing current.

However, in this case, if two operational amplifiers 4A are each provided, one for the discharge current and one for the absorbing current, an overcurrent break in the circuit due to an electric short circuit between the output terminals of the two operational amplifiers 4A may occur; this must be avoided. Therefore, the positive and negative power supplies for both operational amplifiers 4A must be the same; therefore, it is difficult to individually limit the discharge current and the absorbing current.

### SUMMARY OF THE INVENTION

In consideration of the above circumstances, an object of the present invention is to provide a power supply which can individually limit the discharge current and the absorbing current as the output current supplied to the load.

Therefore, the present invention provides a power supply comprising:

a D/A converter (corresponding to a D/A converter 2 in an embodiment explained below) for converting a digital value, which indicates a voltage supplied to a load, to an analog voltage value;

an amplification circuit (corresponding to an operation amplifier 4A in the embodiment explained below) for amplifying the analog voltage value and supplying the amplified voltage value to the load, wherein the amplification circuit has a current limiting control terminal;

a limited current switching circuit, connected to the current limiting control terminal, for changing the amount of a limited current which controls an output current of the amplification circuit, wherein the output current is supplied to the load; and

a switching control circuit (corresponding to a differential amplifier H in the embodiment explained below) for outputting a switching signal by which the limited current switching circuit changes the amount of the limited current.

Typically, the switching control circuit outputs the switching signal based on the polarity of the output current of the amplification circuit.

It is possible that:

the limited current switching circuit includes a control resistor (corresponding to a resistor 3E in the embodiment explained below) which is inserted in parallel between the amplification circuit and a predetermined potential; and

the limited current switching circuit changes the amount of the limited current by determining whether a current is made to flow through the control resistor based on the switching signal.

As a typical example, the limited current switching circuit further includes:

a diode (corresponding to a diode 6 in the embodiment explained below) which is serially connected to the control resistor and whose anode is connected to the current limiting control terminal; and

a PNP transistor (corresponding to a PNP transistor 5 in the embodiment explained below) whose collector is connected between the cathode of the diode and the control resistor,

wherein a current is made to flow through the control resistor when the PNP transistor is on, and no current is made to flow through the control resistor when the PNP transistor is off.

Preferably, the switching control circuit is a differential amplification circuit; and the switching signal output from the differential amplification circuit corresponds to one of a positive voltage and a negative voltage for switching the on/off state of the PNP transistor.

According to the power supply of the present invention, the discharge current and the absorbing current as the output current supplied to the load can be individually limited, that is, a limited current suitable to each state can be made to flow. Therefore, it is possible to prevent unnecessary limited current from flowing (into a negative source or the like) and to reduce the power consumption of the power supply.

### BRIEF DESCRIPTION OF THE DRAWINGS

FIG. 1 is a block diagram showing the structure of the power supply as an embodiment of the present invention.

FIG. 2 is a block diagram showing the structure of a conventional power supply.

### DESCRIPTION OF THE PREFERRED EMBODIMENTS

Hereinafter, an embodiment according to the present invention will be explained in detail with reference to the drawings.

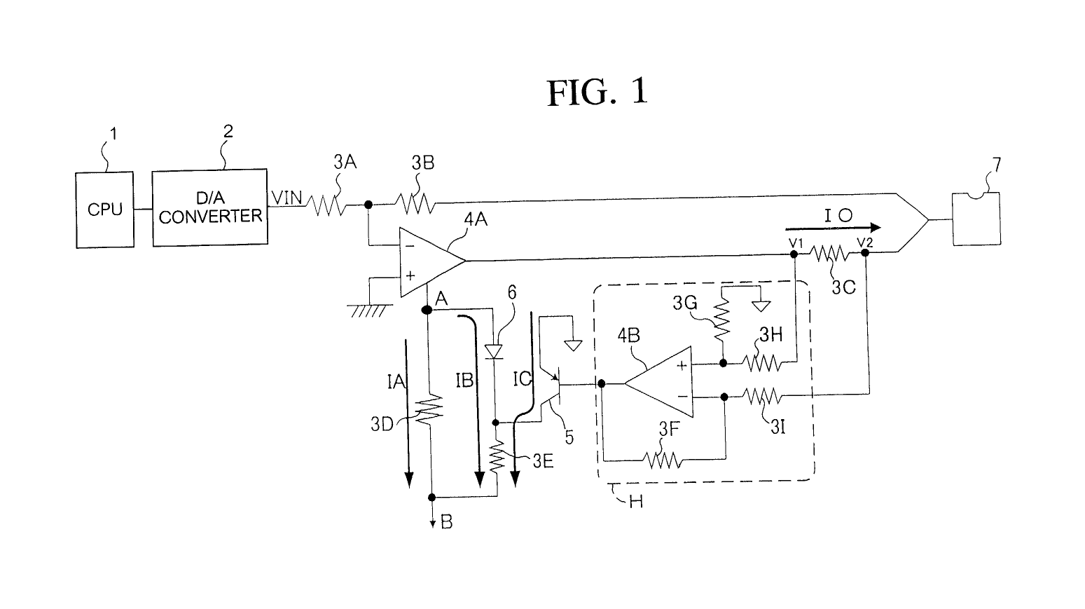

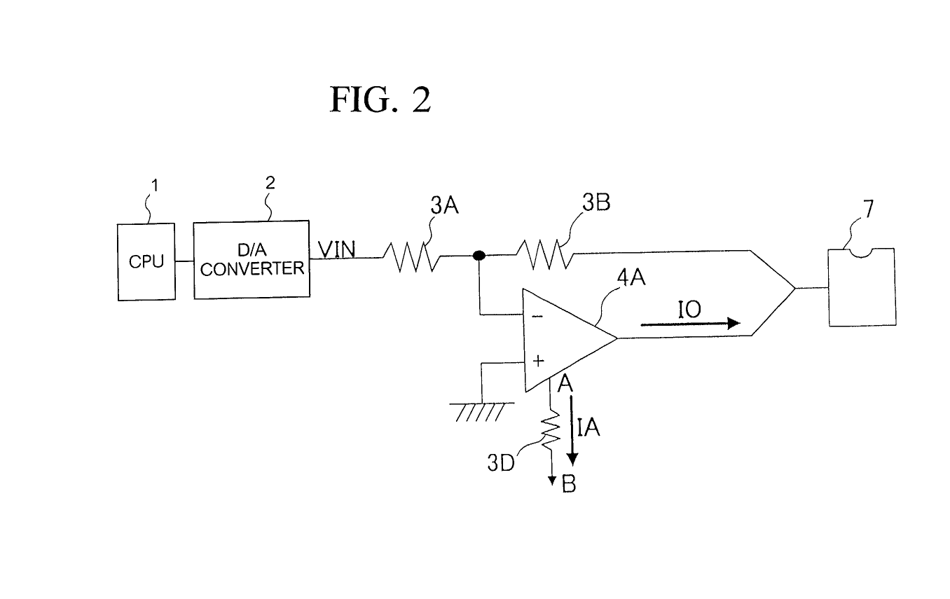

FIG. 1 is a block diagram showing the structure of the power supply as an embodiment of the present invention. In the figure, reference numeral 3C indicates a detection resistor, reference numerals 3E, 3F, 3G, 3H, and 3I indicate resistors, reference numeral 4B indicates an operational amplifier, reference numeral 5 indicates a PNP transistor, and reference numeral 6 indicates a diode. Other portions identical to those in FIG. 2 are given identical reference numerals, and explanations thereof are omitted.

An end of the detection resistor 3C is connected to an output terminal of the operational amplifier 4A and an end of the resistor 3H, and the other end of the detection resistor 3C is connected to the load 7 and an end of the resistor 3I. The positive input terminal of the operational amplifier 4A is set to earth (or ground) potential (i.e., connected to GND).

The other end of the resistor 3H is connected to the positive input terminal of the operational amplifier 4B and an end of the resistor 3G. The other end of the resistor 3G is connected to GND.

The other end of the resistor 3I is connected to the negative input terminal of the operational amplifier 4B and an end of the resistor 3F.

The other end of the resistor 3F is connected to the output terminal of the operational amplifier 4B and the base of the PNP transistor 5.

The emitter of the PNP transistor 5 is connected to GND, and the collector is connected to the cathode of the diode 6 and an end of the resistor 3E. The diode 6 and the resistor 3E are serially connected, and this serially-connected portion and the resistor 3D are connected in parallel between the negative source B and the current limiting control terminal A.

The anode of the diode 6 is connected to the current limiting control terminal A of the operational amplifier 4A and an end of the resistor 3D.

The other end of the resistor 3E is connected to the negative source B.

Below, an example of the operation of the power supply of the present embodiment will be explained with reference to FIG. 1.

When the output current IO flows from the operational amplifier 4A to the load 7, potential difference “V1−V2” is generated between the ends of the detection resistor 3C. Based on the potential difference “V1−V2”, the operational amplifier 4B monitors the polarity of the current value Io of the output current 10. This potential difference is amplified by a differential amplifier H which consists of the operational amplifier 4B and the resistors 3F, 3G, 3H, and 3I.

Given output voltage value Vc of the operational amplifier 4B and resistances RF, RG, RH, and RI of the resistors 3F, 3G, 3H, and 3I, the output voltage value Vc of the operational amplifier 4B is defined by:

Vc=((RI+RF)/(RH+RG))·(RG/RI)·V1−(RF/RI)·V2

In the above formula, if the resistances of the resistors 3F and 3G and the resistances of the resistors 3H and 3I respectively have the following relationships:

RF=RG, and RH=RI,

then the output voltage Vc can be defined by:

Vc=(RF/RI)·(V1−V2)

As shown by the above formula, the polarity of the detected output voltage Vc is determined according to the potential difference “V1−V2” between the ends of the detection resistor 3C.

When the output current IO which flows from the operational amplifier 4A to the load 7 is a discharge current (i.e., Io>0), the potential difference between the ends of the detection resistor 3C is larger than 0 (i.e., V1−V2>0). Accordingly, the output voltage of the operational amplifier 4B has a positive value, so that the PNP transistor is off, that is, in the OFF state. In this situation, current IB having a current value Ib flows through the diode 6 in the forward bias direction, and this current IB flows via the resistor 3E into the negative source B.

That is, the limited current which flows through the current limiting control terminal A is the sum of the current IA, which has the current value Ia and flows through the resistor 3D, and the above-explained current IB (i.e., IA+IB).

Given voltage VA at the current limiting control terminal A and the forward voltage VD of the diode 6, the current value Ia+Ib of the limited current IA+IB is defined by:

Ia+Ib=(VA−VB)/RD+(VA−VD−VB)/RE

Therefore, the output current IO is limited using the limited current IA and the current IB, and the current value Io of the output current IO is G·(Ia+Ib).

Accordingly, when the polarity of the output current 10 is positive, the limited current which flows through the current limiting control terminal A (which is provided for controlling the output current of the operational amplifier 4A) can be larger in comparison with the case when the polarity of the output current 10 is negative. Therefore, the output current IO from the operational amplifier 4A can have a large value.

When the output current 10 which flows from the operational amplifier 4A to the load 7 is an absorbing current (i.e., Io<0), the potential difference between the ends of the detection resistor 3C is V1−V2<0, and the output voltage of the operational amplifier 4B has a negative value. Therefore, the PNP transistor 5 is on, that is, in the ON state.

In this process, the line between the negative source B and the earth potential (GND) is conductive via the resistor 3E and the collector and emitter of the PNP transistor 5, and owing to the relevant potential difference, the current IC flows from GND to the negative source B.

As the current IC flows through the resistor 3E and the voltage drop occurs, the voltage at the cathode of the diode 6 increases and a backward-bias state occurs. Accordingly, the current IB cannot flow, and the current value Ib is thus 0.

Therefore, the current flowing through the negative source B is current “IA+IC”.

However, the limited current which flows through the current limiting control terminal A (which is provided for the operational amplifier 4A) only includes current IA because the current IB does not flow via the diode 6 and the current IC does not affect the operational amplifier 4A.

Therefore, the output current 10 is limited by only the limited current IA, and the current value Io of the output current 10 is G·Ia.

Accordingly, when the polarity of the output current IO is negative, the limited current which flows through the current limiting control terminal A (which is provided for controlling the output current of the operational amplifier 4A) can be smaller in comparison with the case that the polarity of the output current 10 is positive. Therefore, the output current IO from the operational amplifier 4A can be limited to a small value.

In the power supply according to the present invention, the current value Io of the output current IO which flows from the operational amplifier 4A to the load 7 is determined based on the state of the load 7. This function is the same as that possessed by the conventional power supply.

However, in the operation of limiting the current value Io of the output current IO, the discharge current, which should be large, and the absorbing current, which is preferably small, can be individually controlled to each desired level by using the ON/OFF switching operation of the PNP transistor 5. That is, in the control of the present invention, the current IC which flows from the PNP transistor 5 to the resistor 3E (corresponding to the control resistor of the present invention) is used as a switching signal for determining whether the current IB is made to flow via the resistor 3E.

An embodiment of the present invention has been explained above; however, the present invention is not limited to this embodiment, and any modification or variation within the scope and spirit of the claimed invention is possible.

What is claimed is:

1. A power supply comprising:
a D/A converter for converting a digital value, which indicates a voltage supplied to a load, to an analog voltage value;
an amplification circuit for amplifying the analog voltage value and supplying the amplified voltage value to the load, wherein the amplification circuit has a current limiting control terminal;
a limited current switching circuit, connected to the current limiting control terminal, for changing the amount of a limited current which controls an output current of the amplification circuit, wherein the output current is supplied to the load; and
a switching control circuit for outputting a switching signal by which the limited current switching circuit changes the amount of the limited current.

2. A power supply as claimed in claim 1, wherein the switching control circuit outputs the switching signal based on the polarity of the output current of the amplification circuit.

3. A power supply as claimed in claim 1, wherein:
the limited current switching circuit includes a control resistor which is inserted in parallel between the amplification circuit and a predetermined potential; and
the limited current switching circuit changes the amount of the limited current by determining whether a current is made to flow through the control resistor based on the switching signal.

4. A power supply as claimed in claim 3, wherein the limited current switching circuit further includes:
a diode which is serially connected to the control resistor and whose anode is connected to the current limiting control terminal; and
a PNP transistor whose collector is connected between the cathode of the diode and the control resistor,
wherein a current is made to flow through the control resistor when the PNP transistor is on, and no current is made to flow through the control resistor when the PNP transistor is off.

5. A power supply as claimed in claim 4, wherein:
the switching control circuit is a differential amplification circuit; and
the switching signal output from the differential amplification circuit corresponds to one of a positive voltage and a negative voltage for switching the on/off state of the PNP transistor.
